(19) United States
(12) Patent Application Publication
(10) Pub. No.: US 2024/0064931 A1
(43) Pub. Date: Feb. 22, 2024

(54) IMMERSION COOLING SYSTEM WITH FIRST AND SECOND PRIMARY LOOPS

(71) Applicant: Intel Corporation, Santa Clara, CA (US)

(72) Inventors: Jimmy CHUANG, Taipei (TW); Yuehong FAN, Shanghai (CN); Jing-Hua HE, Portland, OR (US); Sandeep AHUJA, Portland, OR (US); Jay WU, Taipei (TW); Dongrui XUE, Shanghai (CN); Xiaowei LI, Shenzhen (CN)

(21) Appl. No.: 18/499,112

(22) Filed: Oct. 31, 2023

(30) Foreign Application Priority Data
Oct. 7, 2023 (WO) PCT/CN2023/123185

(51) Int. Cl. H05K 7/20; G06F 1/20; H01L 23/473

(52) U.S. Cl. CPC H05K 7/20263; G06F 1/20; H01L 23/473; H05K 7/20236; H05K 7/20254; H05K 7/20763; H05K 7/20272

(57) ABSTRACT

An apparatus is described. The apparatus includes a coolant distribution unit having a first primary loop output to provide first cooled immersion liquid to an immersion chamber and a second primary loop output to provide second cooled immersion liquid to one or more cold plates within the immersion chamber.

### BACKGROUND

With the emergence of high performance centralized computing (such as cloud computing, artificial intelligence, big data computing, etc.) the computational demands being placed on the underlying electronics cause the electronics to generate significant amounts of heat. As such, engineers are focused on improving the ways in which heat can be removed from the electronics.

### BRIEF DESCRIPTION OF DRAWINGS

FIG. 1 shows an immersion cooling system;

FIG. 2 shows an improved immersion cooling system;

FIGS. 3a, 3b, 3c, 3d, 3e, 3f, 3g, 3h, 3i and 3j show an improved CDU;

FIGS. 4a and 4b shows an improved immersion chamber;

FIGS. 5a, 5b and 5c show an improved cold plate;

FIG. 6 shows a data center.

### DETAILED DESCRIPTION

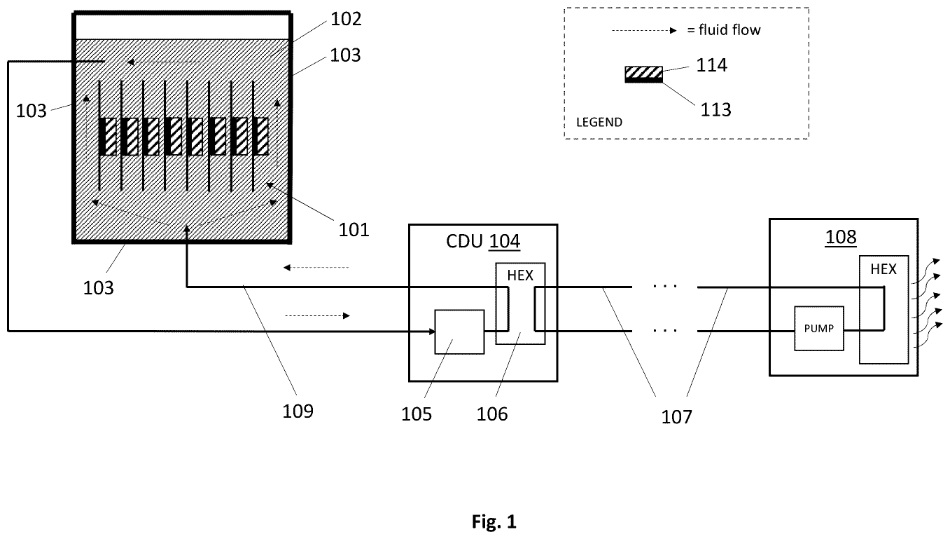

FIG. 1 depicts an immersion cooling system. As observed in FIG. 1, a plurality of electronic circuit boards 101 are immersed in a dielectric liquid 102 that electrically isolates the exposed electrical nodes of the electronic circuit boards 101 and their respective electronic components (FIG. 1 depicts a side view of the circuit boards 101 oriented vertically within the liquid 102). The electronic components, when in operation, generate heat which is transferred to the liquid 102. The liquid 102 has a higher heat transfer coefficient than air which enables heat to be removed from the electrical components more effectively than would otherwise be achievable in an air-cooled environment.

The immersion bath chamber 103 is also fluidically coupled through a “primary” loop 109 to a coolant distribution unit (CDU) 104 that includes a pump 105 and heat exchanger 106. During continued operation of the electronic components, the liquid's temperature will rise as a consequence of the heat it receives from the operating electronics 101. The pump 105 draws the warmed liquid 102 from the immersion bath chamber 103 to the heat exchanger 106. The heat exchanger 106 transfers heat from the warmed fluid to another liquid within a secondary cooling loop 107 that is fluidically coupled to a cooling tower and/or chilling unit 108. The removal of the heat from the liquid 102 by the heat exchanger 106 reduces the temperature of the liquid which is then returned to the chamber 103 as cooled liquid.

In a high computing environment, such as a data center, the respective CDUs of multiple immersion bath chambers are coupled to the secondary loop 107, and, the cooling tower and/or chilling unit 108 removes the heat generated by the electronics within the multiple immersion bath chambers from the data center.

Unfortunately, within the chamber 103, the flow of cooled liquid 102 over the chip packages 113 of the higher performance semiconductor chips that generate the most heat (e.g., CPUs, GPUs, etc.) is insufficient to adequately cool these chips. To alleviate the problem, the chip packages 113 can have heat sinks 114 mounted thereon to improve the transfer of heat from the chip packages 113 to the cooling liquid 102.

Unfortunately, the chip packages 113 and their mounted heat sinks 114 are commonly located towards the middle of their respective circuit boards 101, and, the circuit boards 101 themselves are arranged with narrow spacings between them.

As a consequence, the open space around the packages 113 and heat sinks 114 through which the liquid 102 is supposed flow is narrow, which, in turn, presents a high fluidic impedance that causes the cooled liquid within the chamber 103 to flow substantially around the circuit boards 101 rather than through the narrow spaces between them. As such, there is reduced fluid flow through the heat sinks 114 resulting in reduced heat transfer from the chips to the liquid 102.

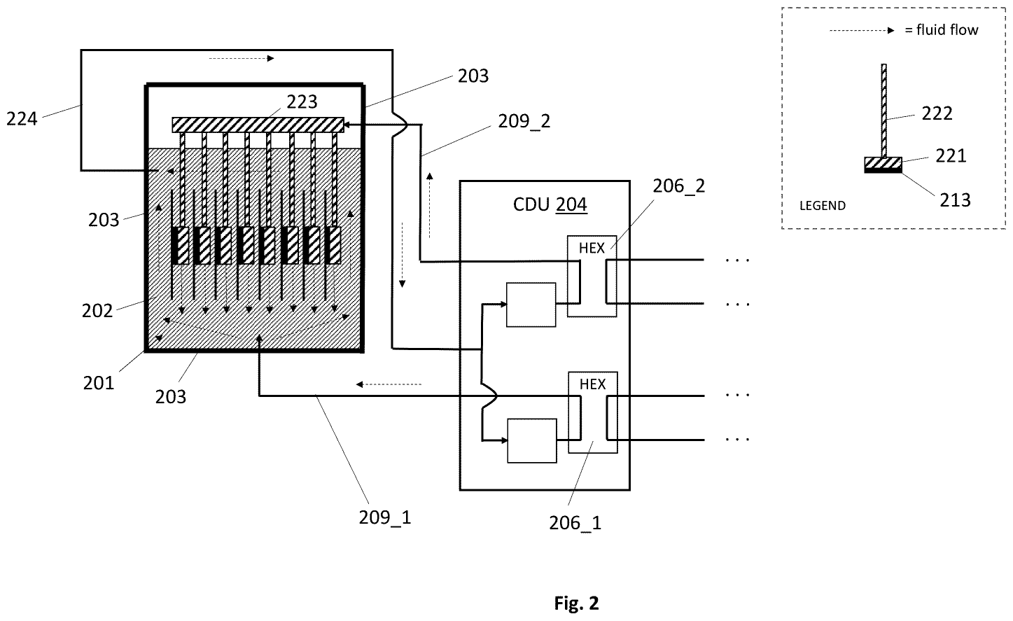

An improved approach, observed in FIG. 2, is to attach respective cold plates 221 to the packages 213 of the high performance chips, where, the cold plates 221 receive cooled fluid from a second primary loop 209_2 that is provided by the CDU 204.

Here, as described in more detail below, the CDU 204 not only provides a first primary loop of cooled fluid 209_1 that cools the electronics 201 in the chamber 203 similar to the system described just above with respect to FIG. 1, but also, provides a second primary loop 209_2 that is fed to a manifold 223.

The manifold 223 directs the second primary fluid 209_2 into fluidic channels 222 that are coupled to the respective cold plates 221 that are mounted to the high performance chip packages 213 within the immersion bath 202. The second primary fluid 209_2 removes heat from the high performance semiconductor chips as it flows through the cold plates 221 and then exits the cold plates 221 and flow into the chamber immersion bath 202. The warmed first and second primary fluids 209_1, 209_2 are then directed from the chamber 203 back to the CDU 204 through a warmed fluid line 224. The CDU 204 then generates the first and second primary cooled loop fluids 209_1, 209_2 from the received warmed fluid and the process repeats.

Importantly, the second primary fluid 209_2, as provided by the CDU 204, is colder than the first primary fluid 209_1 and/or has a higher flow rate (and/or higher volumetric flow rate) than the first primary fluid 209_1. As such, the high performance semiconductor chips have their heat removed by a fluid flow 209_2 that is colder and/or faster than the fluid flow 209_1 that would otherwise cool them in the system of FIG. 1.

Here, the manifold 223, fluidic channels 222 and cold plates 221 overcome the high fluidic impedance associated with the narrow regions of the immersion bath 202 in the vicinity of the high performance semiconductor chip packages. Because colder and/or faster fluid flow corresponds to greater heat removal capability, the system of FIG. 2 can adequately cool the high performance chips.

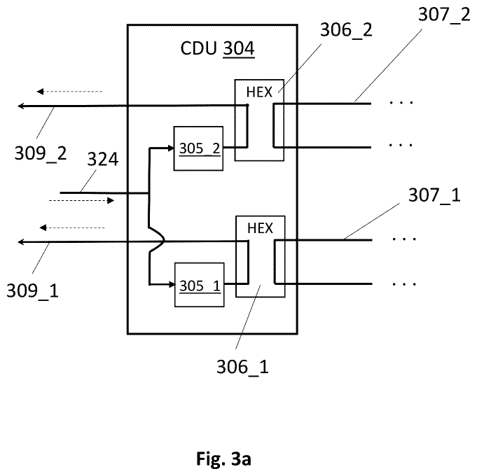

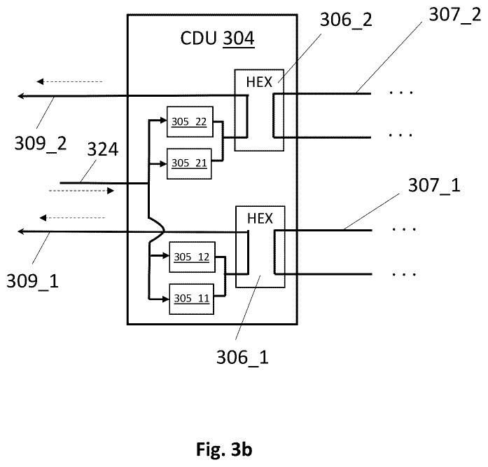

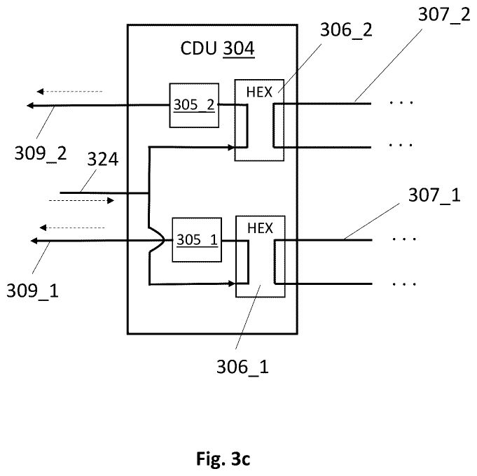

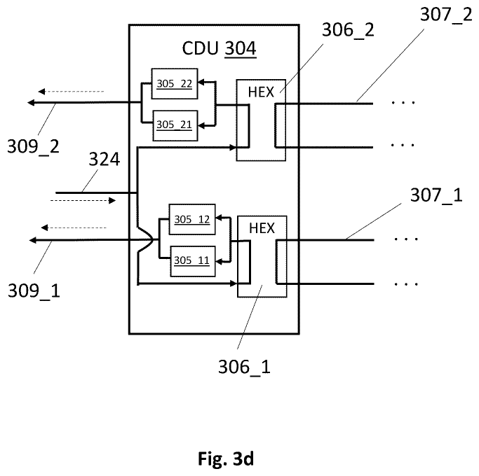

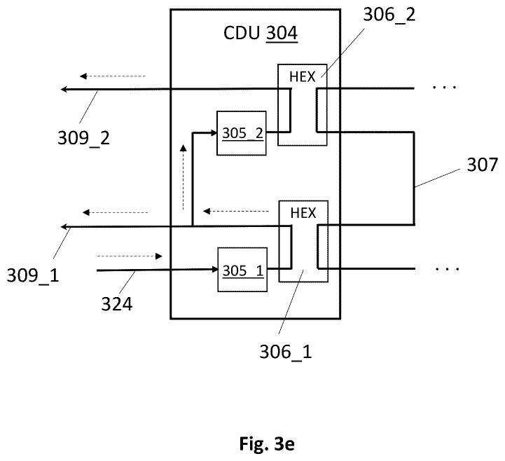

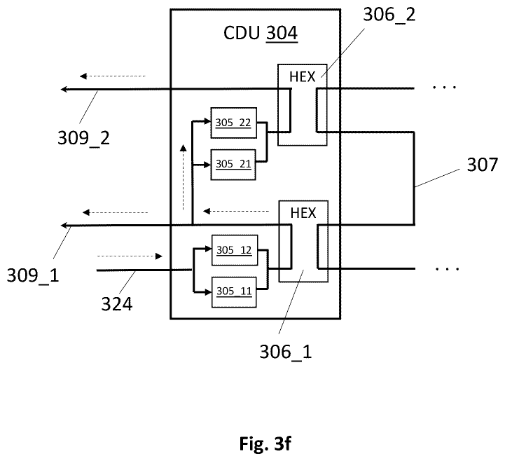

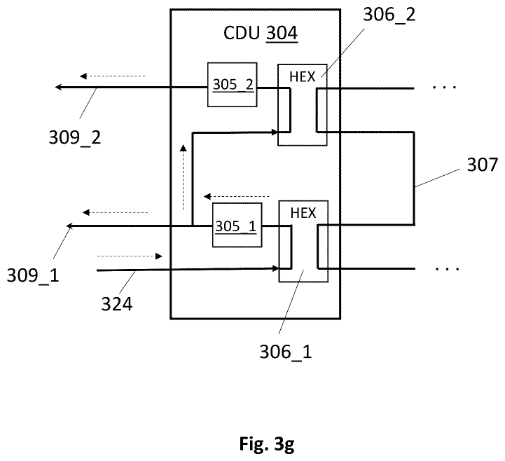

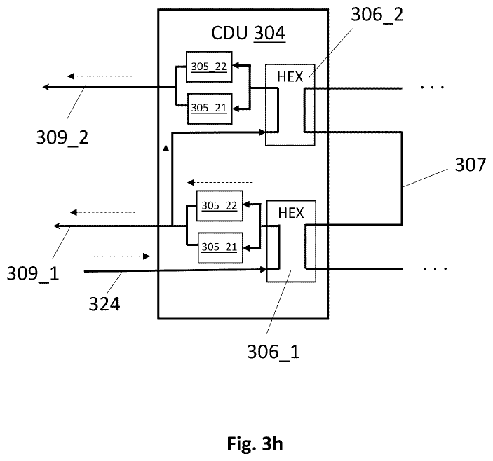

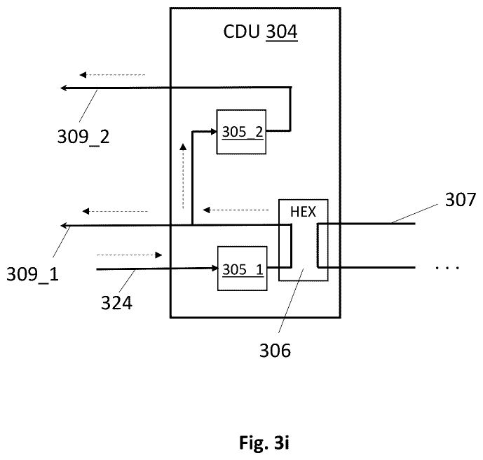

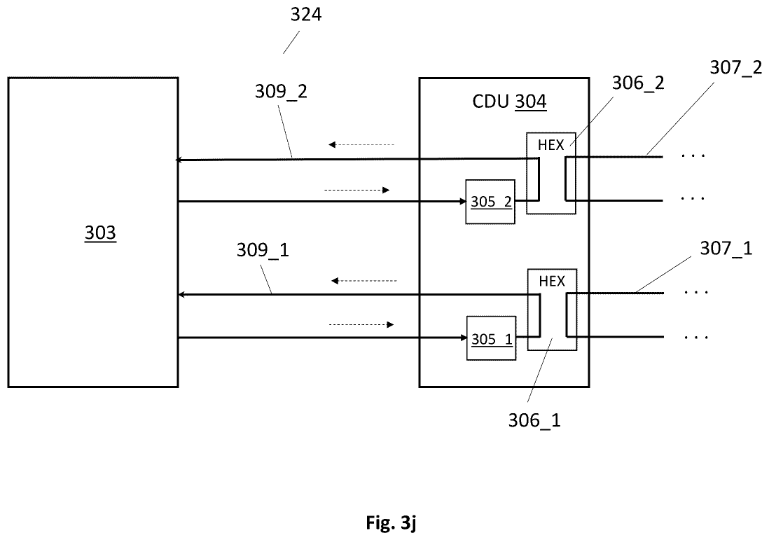

FIGS. 3a through 3j depict different embodiments for a CDU that provides both first and second primary cooling loops to an immersion chamber as described just above.

FIG. 3a shows a first CDU embodiment 304 in which the larger data center provides first and second secondary loops 307_1, 307_2 that are respectively coupled to the CDU's first and second primary loops 309_1, 309_2 through respective heat exchangers 306_1, 306_2. That is, the CDU's first primary loop 309_1 flows through a first pump 305_1 and a first heat exchanger 306_1, while, the CDU's second primary loop 309_2 flows through a second pump 305_2 and a second heat exchanger 306_2.

As observed in FIG. 3a, the common warmed fluid 324 is split into the first and second primary loops 309_1, 309_2. The warmed liquid of the first primary loop 309_1 flows through a first heat exchanger 306_1 that transfers heat from the first primary loop to the liquid of the first secondary loop 307_1. The removal of the heat cools the liquid of the first primary loop 309_1 which then flows to the immersion chamber. The warmed liquid of the second primary loop 309_2 flows through a second heat exchanger 306_2 that transfers heat from the second primary loop to the liquid of the second secondary loop 307_2. The removal of the heat cools the liquid of the second primary loop 309_2 which then flows to the manifold within the immersion chamber.

In the particular embodiment of FIG. 3a, according to one embodiment, the fluid of the second secondary loop 307_2 is colder than the liquid of the first secondary loop fluid 307_1. In this case, at least for a same volumetric flow rate through the first and second heat exchangers 306_1, 306_2 (e.g., the respective pumps 305_1, 305_2 of the first and second primary loops 309_1, 309_2 pump at a same rate), the second heat exchanger 306_2 will remove more heat from the second primary loop 309_2 than the first heat exchanger 306_1 will remove from the first primary loop 309_1.

If pump 305_2 pumps the second primary loop 309_2 at a faster rate than pump 305_1 pumps the first primary loop 309_1, the liquid of the second primary loop 309_2 can be both colder and faster than the liquid of the first primary loop 309_1 if there exists a large enough temperature difference between the first and second secondary loops 307_1, 307_2.

Here, the faster a primary loop fluid is pumped through a heat exchanger, the less heat the heat exchanger will transfer to a secondary primary loop. Thus, increasing the pump speed for the second primary loop 309_2 will cause the second heat exchanger 306_2 to transfer less heat to the second secondary loop 307_2 than a slower pump speed would. Nevertheless, even if the second primary loop 309_2 is pumped to a faster flow rate than the first primary loop 309_1, more heat can still be removed from the second primary loop 309_2 than the first primary loop 309_1 if the second secondary loop 307_2 is significantly colder than the first secondary loop 307_1. In this case, the second primary loop 309_2 will be both colder and have a faster flow rate than the first primary loop fluid 309_1, which might be ideal for cooling the high performance semiconductor chips.

Other parameters that can be set to effect more heat transfer from the second primary loop heat exchanger 306_2 than from the first primary loop heat exchanger 306_1 is the relative volumetric flow rates of the first and second secondary loops 307_1, 307_2. Specifically, if the second secondary loop 307_2 flows at a faster volumetric flow rate than the first secondary loop 307_1, more heat will be absorbed by the second secondary loop 307_2 as it flows through the second heat exchanger 306_2. As a consequence, the second heat exchanger 306_2 will remove more heat from the second primary loop 309_2 than the first heat exchanger 306_1 will remove from the first primary loop 309_1.

The CDU embodiment of FIG. 3b shows the CDU embodiment of FIG. 3a but with a redundant pump 305_12, 305_22 for both the first and second primary loops 309_1, 309_2. A redundant pump ensures the corresponding primary loop will continue to flow if one of the pumps for the particular loop fails.

The CDU embodiments of FIGS. 3c and 3d correspond to the embodiments of FIGS. 3a and 3b but where the pumps are located on the output side of the heat exchangers rather than the input side.

The above described CDU embodiments create first and second primary loops 309_1, 309_2 that are isolated from one another after the split in the warmed fluid return feed 324. By contrast, the CDU embodiment of FIG. 3e shows another approach in which lower temperature is effected for the second primary loop 309_2 by flowing the second primary loop 309_2 through first and second heat exchangers 306_1, 306_2, whereas, the first primary loop 309_1 flows only through the first heat exchanger 306_1. Here, because a heat exchanger removes heat from its primary fluid, running the second primary loop 309_2 through two heat exchangers will cause more heat to be removed from the second primary 309_2 (because heat is removed from the second primary loop 309_2 twice, whereas, heat is removed from the first primary loop 309_1 only once).

Comparing the approach of FIG. 3e with the approaches of FIGS. 3a through 3d, note that the split that separates the first and second primary loops 309_1, 309_2 is located between the first and second heat exchangers 306_1, 306_2 rather than before both heat exchangers 306_1, 306_2. Importantly, the approach of FIG. 3e can be used in environments where the data center only provides one secondary loop rather than two different secondary loops having different (e.g., temperature) characteristics. In this case, as observed in FIG. 3e, the single secondary loop 307 is routed through both the first and second heat exchangers.

The approach of FIG. 3e can also be used in embodiments where the data center provides two secondary loops having different characteristics as described above with respect to FIGS. 3a through 3d above. In this case, the CDU of FIG. 3e could achieve lower second primary loop 309_2 temperatures than any of the CDUs of FIGS. 3a through 3d because the CDU of FIG. 3e would not only be cooled by a colder secondary loop (like the approaches of FIGS. 3a through 3d) but would also be cooled by two heat exchanges (unlike the approaches of FIGS. 3a through 3d).

The CDU embodiment of FIG. 3f shows the CDU embodiment of FIG. 3e but with a redundant pump for both the first and second primary loops 309_1, 309_2.

The CDU embodiments of FIGS. 3g and 3h correspond to the embodiments of FIGS. 3e and 3f but where the pumps are located on the output side of the heat exchangers rather than the input side.

FIG. 3i shows another CDU embodiment that includes only one heat exchanger 306. In this case, the second primary loop 309_2 emphasizes higher flow rate to cool the high performance semiconductor chips rather than lower temperature. For example, the second primary loop's pump 305_2 pumps the second primary loop 309_2 to a much higher flow rate and/or volumetric flow rate than what the first primary loop's pump 305_1 pumps the first primary loop 309_1 to.

FIG. 3j shows another CDU embodiment where the split between the first and second primary loops 309_1, 309_2 is created at the output of the chamber 303 rather than within the CDU. Here, the design of the CDU could be like any of those of FIGS. 3a through 3d but, there are separate inputs to the CDU for the first primary loop and the second primary loop.

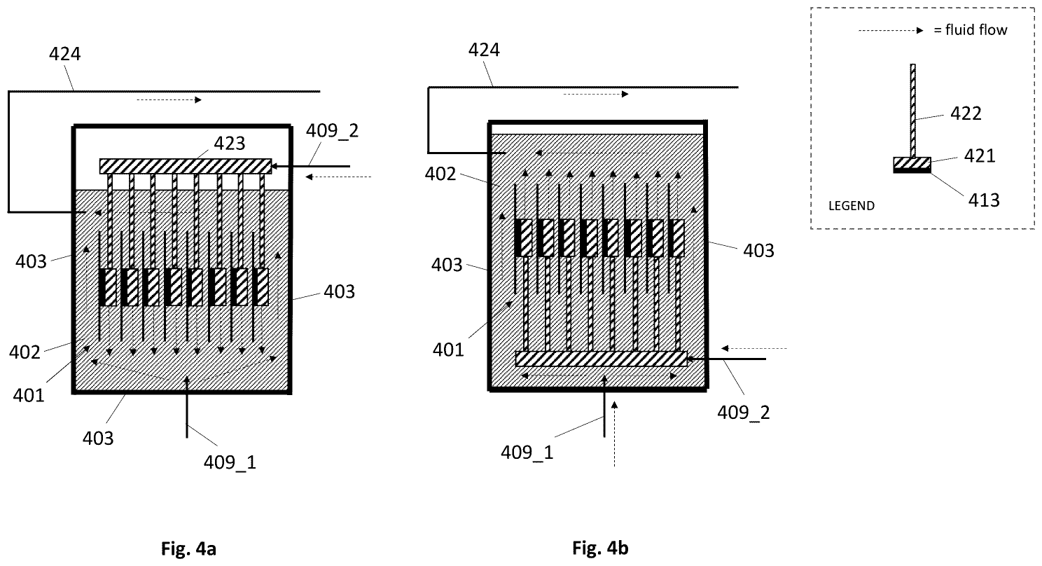

FIGS. 4a and 4b show different immersion chamber designs that can be used with any/all of the CDUs described above with respect to FIGS. 3a through 3i. The chamber designs of FIGS. 4a and 4b can also be modified to have first and second primary loop outputs as observed in FIG. 3j. The chamber designs of FIG. 4a depict electronics 401 within fluid 402 within a chamber, a first primary loop input 409_1, a second primary loop input 409_2, a manifold 423, cold plates 421, conduit lines 422 coupled between the cold plates 421 and the manifold 423, and, common return feed 424 back the CGU.

As observed in FIG. 4a, the second primary loop manifold 423 is located above the electronics 401 within the immersion bath 402, whereas, as observed in FIG. 4b, the secondary primary loop manifold 423 is located beneath the electronics 401 within the immersion bath 402.

Conceivably, the hook-ups of the conduit lines 422 between the manifold 423 and the cold plates 421 for the second primary loop 409_2 can be more easily made with the embodiment of FIG. 4a because an operator is working above the electronics 401 rather than beneath them. For example, in the approach of FIG. 4b, the conduit lines 422 between the manifold 423 and cold plates 421 are effected with precisely located connectors on the manifold 423 that conduit lines 422 are supposed to “plug-into” when an electronic board is being immersed into the immersion bath 402. The precision needed to make such a connection may be cumbersome. By contrast, in the approach of FIG. 4a, an operator can first connect a conduit line 422 to its cold plate 421, then mount the cold plate's circuit board into the immersion bath 402, then connect the conduit line 422 to the manifold 423.

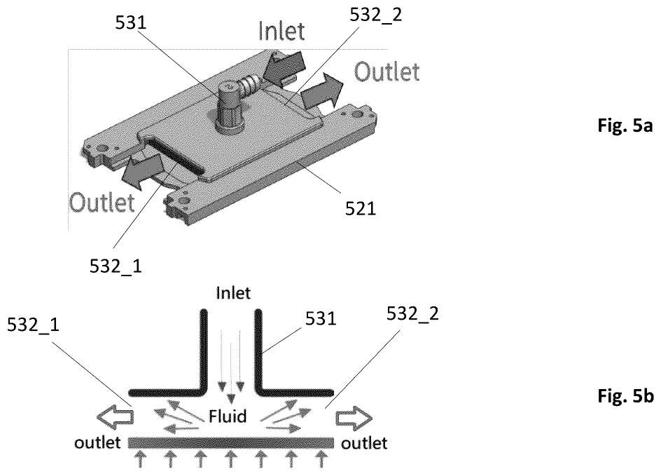

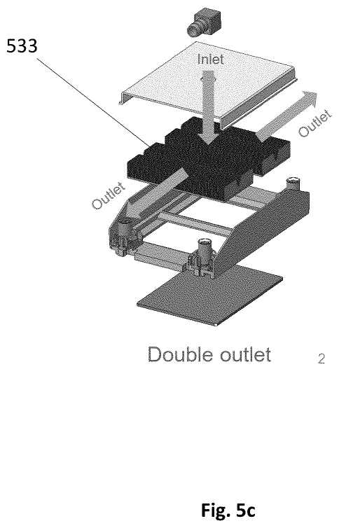

FIGS. 5a, 5b and 5c pertain to an embodiment of a cold plate 521 that is particularly suitable for use in a second primary cooling loop as described at length above. Here, the cold plate 521 is mounted, or otherwise mechanically coupled to, the semiconductor chip package of one or more, e.g., high performance semiconductor chips. A conduit line is coupled to the inlet 531 and cooled fluid (e.g., from a manifold that the other end of the conduit line is coupled to) is forcefully injected onto the floor of the cold plate, the underside of which receives heat from the underlying chip package.

As observed in FIG. 5a, the forceful injection of the cooled fluid can be directed into a middle area of the cold plate floor that itself is directly above a “hot spot” on the lid of the underlying semiconductor chip package. Additionally, the cold plate 521 has two outlets 532_1, 532_2 for the warmed fluid to escape the cold plate 521 and enter the immersion bath. The presence of two outlets 532_1, 532_2 reduces the fluidic impedance of the cold plate 521 (e.g., as observed by the second primary loop's respective pump(s)) which, in turn, increases the flow rate of the cooled fluid that enters the cold plate 521. The higher flow rate improves the heat removal capacity of the cold plate 521, which, in turn, allows for adequate cooling of higher performance/power semiconductor chips within the chip package that the cold plate 521 is mounted to.

FIG. 5c shows a more detailed exploded view of the cold plate of FIGS. 5a and 5b. Notably, in the embodiment of FIG. 5c, the floor of the cold plate that is impinged upon by the cooled liquid can be structured, e.g., with fins, to increase the surface area over which heat from the semiconductor chip package is transferred to the liquid.

A cooling system having first and second primary loops as described above can also be used to realize better energy consumption efficiencies. For example, if the electronics in the immersion system are being underutilized, one of the primary loops can be stopped (its pump is shut down). For example, the first primary loop that provides cooled fluid to the immersion bath within the chamber can be shut down and only the second primary loop that feeds the cold plates of the high performance semiconductor chips remains operative.

Here, because the liquid volume of the second primary loop can be much less than the liquid volume of the first primary loop, the second primary loop's pump(s) can be less powerful and therefore consume less energy than the first primary loop's pump(s). Thus, shutdown of the more powerful first primary loop pump(s) results in considerable energy consumption savings.

Likewise, both primary loops are placed in operation when the electronics are being more heavily utilized. Nevertheless, the pump rates of the first and/or second primary loop pumps can be adjusted in view of the overall electronics' workload (first primary loop pump speed is adjusted) and/or the workload placed on the high performance semiconductor chips (second primary loop speed is adjusted).

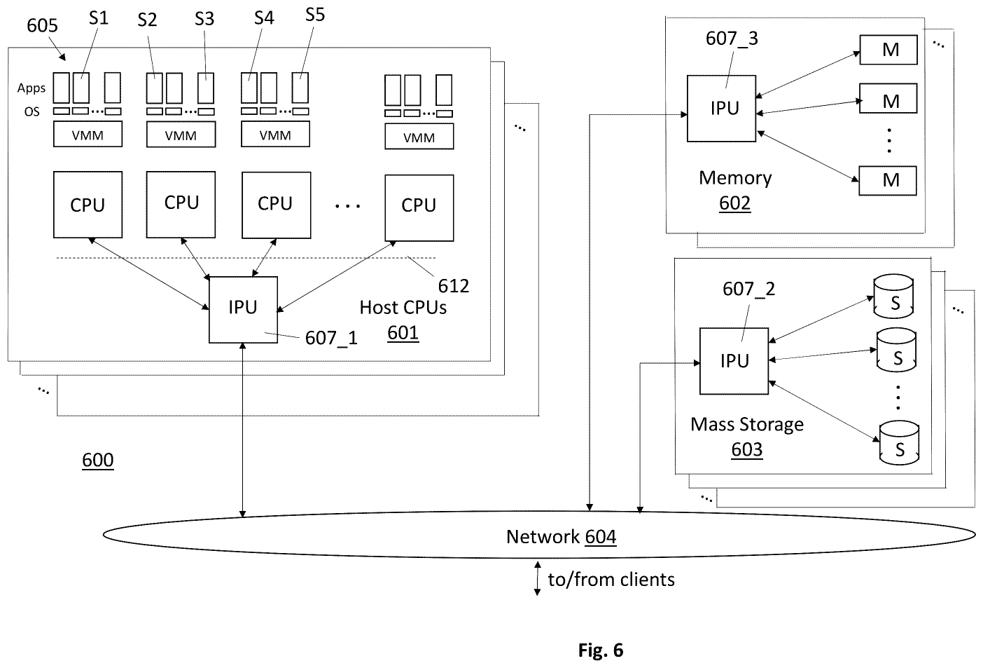

FIG. 6 shows a new, emerging data center environment in which “infrastructure” tasks are offloaded from traditional general purpose “host” CPUs (where application software programs are executed) to an infrastructure processing unit (IPU) or data processing unit (DPU) any/all of which are hereafter referred to as an IPU.

Networked based computer services, such as those provided by cloud services and/or large enterprise data centers, commonly execute application software programs for remote clients. Here, the application software programs typically execute a specific (e.g., “business”) end-function (e.g., customer servicing, purchasing, supply-chain management, email, etc.). Remote clients invoke/use these applications through temporary network sessions/connections that are established by the data center between the clients and the applications. A recent trend is to strip down the functionality of at least some of the applications into more finer grained, atomic functions (“micro-services”) that are called by client programs as needed. Micro-services typically strive to charge the client/customers based on their actual usage (function call invocations) of a micro-service application.

In order to support the network sessions and/or the applications' functionality, however, certain underlying computationally intensive and/or trafficking intensive functions (“infrastructure” functions) are performed.

Examples of infrastructure functions include routing layer functions (e.g., IP routing), transport layer protocol functions (e.g., TCP), encryption/decryption for secure network connections, compression/decompression for smaller footprint data storage and/or network communications, virtual networking between clients and applications and/or between applications, packet processing, ingress/egress queuing of the networking traffic between clients and applications and/or between applications, ingress/egress queueing of the command/response traffic between the applications and mass storage devices, error checking (including checksum calculations to ensure data integrity), distributed computing remote memory access functions, etc.

Traditionally, these infrastructure functions have been performed by the CPU units “beneath” their end-function applications. However, the intensity of the infrastructure functions has begun to affect the ability of the CPUs to perform their end-function applications in a timely manner relative to the expectations of the clients, and/or, perform their end-functions in a power efficient manner relative to the expectations of data center operators.

As such, as observed in FIG. 6, the infrastructure functions are being migrated to an infrastructure processing unit (IPU) 607. FIG. 6 depicts an exemplary data center environment 600 that integrates IPUs 607 to offload infrastructure functions from the host CPUs 601 as described above.

As observed in FIG. 6, the exemplary data center environment 600 includes pools 601 of CPU units that execute the end-function application software programs 605 that are typically invoked by remotely calling clients. The data center also includes separate memory pools 602 and mass storage pools 603 to assist the executing applications. The CPU, memory storage and mass storage pools 601, 602, 603 are respectively coupled by one or more networks 604.

Notably, each pool 601, 602, 603 has an IPU 607_1, 607_2, 607_3 on its front end or network side. Here, each IPU 607 performs pre-configured infrastructure functions on the inbound (request) packets it receives from the network 604 before delivering the requests to its respective pool's end function (e.g., executing application software in the case of the CPU pool 601, memory in the case of memory pool 602 and storage in the case of mass storage pool 603).

As the end functions send certain communications into the network 604, the IPU 607 performs pre-configured infrastructure functions on the outbound communications before transmitting them into the network 604. The communication 612 between the IPU 607_1 and the CPUs in the CPU pool 601 can transpire through a network (e.g., a multi-nodal hop Ethernet network) and/or more direct channels (e.g., point-to-point links) such as Compute Express Link (CXL), Advanced Extensible Interface (AXI), Open Coherent Accelerator Processor Interface (OpenCAPI), Gen-Z, etc.

Depending on implementation, one or more CPU pools 601, memory pools 602, mass storage pools 603 and network 604 can exist within a single chassis, e.g., as a traditional rack mounted computing system (e.g., server computer). In a disaggregated computing system implementation, one or more CPU pools 601, memory pools 602, and mass storage pools 603 are separate rack mountable units (e.g., rack mountable CPU units, rack mountable memory units (M), rack mountable mass storage units (S)).

In various embodiments, the software platform on which the applications 605 are executed include a virtual machine monitor (VMM), or hypervisor, that instantiates multiple virtual machines (VMs). Operating system (OS) instances respectively execute on the VMs and the applications execute on the OS instances. Alternatively or combined, container engines (e.g., Kubernetes container engines) respectively execute on the OS instances. The container engines provide virtualized OS instances and containers respectively execute on the virtualized OS instances. The containers provide isolated execution environment for a suite of applications which can include, applications for micro-services.

Notably, the respective electronic boards/components of the data center components described above can be cooled according to the teachings described above with respect to FIGS. 2, 3a through 3j, 4a and 4b, and, 5a and 5b.

Embodiments of the invention may include various processes as set forth above. The processes may be embodied in program code (e.g., machine-executable instructions). The program code, when processed, causes a general-purpose or special-purpose processor to perform the program code's processes. Alternatively, these processes may be performed by specific/custom hardware components that contain hard wired interconnected logic circuitry (e.g., application specific integrated circuit (ASIC) logic circuitry) or programmable logic circuitry (e.g., field programmable gate array (FPGA) logic circuitry, programmable logic device (PLD) logic circuitry) for performing the processes, or by any combination of program code and logic circuitry.

Elements of the present invention may also be provided as a machine-readable storage medium for storing the program code. The machine-readable medium can include, but is not limited to, floppy diskettes, optical disks, CD-ROMs, and magneto-optical disks, FLASH memory, ROMs, RAMs, EPROMs, EEPROMs, magnetic or optical cards or other type of media/machine-readable medium suitable for storing electronic instructions.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a coolant distribution unit comprising a first primary loop output to provide first cooled immersion liquid to an immersion chamber and a second primary loop output to provide second cooled immersion liquid to one or more cold plates within the immersion chamber.

2. The apparatus of claim 1 wherein the coolant distribution unit comprises a first heat exchanger coupled to the first primary loop output and a second heat exchanger coupled to the second primary loop output.

3. The apparatus of claim 2 wherein an output of the first heat exchanger is coupled to an input of the second heat exchanger.

4. The apparatus of claim 1 wherein the coolant distribution unit comprises a heat exchanger and wherein the first primary loop output and the second primary loop output are coupled to an output of the heat exchanger.

5. The apparatus of claim 4 further comprising at least one second primary loop pump coupled between the heat exchanger output and the second primary loop output.

6. The apparatus of claim 1 wherein the coolant distribution unit comprises a warmed fluid input and wherein the first primary loop output and the second primary loop output are coupled downstream from the warmed fluid input.

7. The apparatus of claim 1 wherein at least one of the first primary loop output and second primary loop output are coupled to a first pump and a second redundant pump.

8. A method, comprising:
splitting immersion chamber fluid into a first primary loop and a second primary loop;
cooling the second primary loop to a cooler temperature than the first primary loop, and/or, pumping the second primary loop to a higher flow rate than the first primary loop;
pumping the first primary loop into an immersion bath within the immersion chamber; and,
pumping the second primary loop through at least one cold plate that is coupled to a semiconductor chip package within the immersion bath.

9. The method of claim 8 further comprising cooling the first primary loop with a first secondary loop and cooling the second primary loop with a second secondary loop.

10. The method of claim 9 wherein the second secondary loop has a colder temperature than the first secondary loop.

11. The method of claim 8 further comprising pumping the second primary loop through a manifold that feeds multiple conduit lines to multiple respective cold plates that are mounted to respective semiconductor chip packages.

12. The method of claim 8 wherein the splitting is performed within a coolant distribution unit.

13. The method of claim 8 wherein the splitting is performed before the first primary loop is cooled and before the second primary loop is cooled.

14. The method of claim 8 wherein the splitting is performed downstream from a heat exchanger that cools the first primary loop.

15. A data center, comprising:
a network;
a CPU pool coupled to the network;
a memory pool coupled to the network;
a mass storage pool coupled to the network; and,
an immersion chamber, the immersion chamber containing an immersion liquid wherein electronics from the CPU pool, the memory pool and/or the mass storage pool are immersed within the immersion liquid, the immersion chamber comprising a first input that receives a first primary loop of cooled immersion liquid that flows into the immersion liquid, the electronics comprising a semiconductor chip package coupled to a cold plate, the cold plate coupled to a conduit line that receives at least a portion of a second primary loop of cooled immersion liquid.

16. The data center of claim 15 wherein the cold plate comprises an inlet that injects the at least a portion of the second primary loop of cooled immersion liquid directly on a floor of the cold plate that is coupled to the semiconductor chip package.

17. The data center of claim 16 wherein the cold plate has more than one outlet through which the at least a portion of the second primary loop of liquid flows into the immersion liquid through after being warmed by heat from the semiconductor chip package.

18. The data center of claim 15 wherein the data center further comprises a coolant distribution unit that provides the first primary loop of cooled immersion liquid and the second primary loop of cooled immersion liquid.

19. The data center of claim 18 coolant distribution unit comprises a first heat exchanger to cool the first primary loop and a second heat exchanger to cool the second primary loop and wherein the first heat exchanger is coupled to a first secondary loop and the second heat exchanger is coupled to a second secondary loop.

20. The data center of claim 19 further comprising a manifold having an output coupled to the conduit line that provides a portion of the second primary loop of cooled immersion liquid to the conduit line, the manifold comprising other outputs that provide other portions of the second primary loop of cooled immersion liquid to other conduit lines that are coupled to other cold plates that are coupled to other semiconductor chip packages within the immersion liquid.
